(19) United States
(12) Patent Application Publication
(10) Pub. No.: US 2026/0282285 A1
(43) Pub. Date: Sep. 17, 2026

(54) TRANSONIC AND SUPERSONIC TWO-PHASE FLOW FOR ELECTRONIC COOLING

(71) Applicant: University of Central Florida Research Foundation, Inc., Orlando, FL (US)

(72) Inventors: Yoav Peles, Orlando, FL (US); Soroush Niazi, Orlando, FL (US); Sameer Rao, Salt Lake City, UT (US)

(73) Assignee: University of Central Florida Research Foundation, Inc., Orlando, FL (US)

(21) Appl. No.: 19/568,315

(22) Filed: Mar. 16, 2026

Related U.S. Application Data
(60) Provisional application No. 63/773,094, filed on Mar. 17, 2025.

(51) Int. Cl. H05K 7/20

(52) U.S. Cl. CPC H05K 7/20345; H05K 7/20327; H05K 7/20936; H05K 7/20945

(57) ABSTRACT

In accordance with at least one aspect of this disclosure, a system for cooling a heat-generating component includes a cooling device having a first plate defining an inlet, an outlet, and an envelope for the heat-generating component. A second plate is mounted against the first plate and defines a converging-diverging (CD) nozzle therein, with an inlet end of the CD nozzle in fluid communication with the inlet of the first plate, with an outlet end of the CD nozzle in fluid communication with the outlet of the first plate. The envelope for the heat-generating component is positioned between the inlet and the outlet to ensure thermal contact with a supersonic/transonic, two-phase fluid flow emerging from a throat of the CD nozzle.

### CROSS REFERENCE TO RELATED APPLICATIONS

This Application claims priority to U.S. Provisional Patent Application No. 63/773,094, filed Mar. 17, 2026. The entire contents of this application are incorporated herein by reference in their entirety.

### BACKGROUND

### 1. Field

The present disclosure relates to heat transfer, and more particularly to cooling such as for use with high-power generating electronics.

### 2. Description of Related Art

There is an evolving problem of cooling high-power heat generating electronics. This is typically being addressed by air cooling or liquid cooling at atmospheric conditions. The conventional techniques have been considered satisfactory for their intended purpose. However, there is an ever-present need for improved systems and methods for cooling such as for heat generating electronic components. This disclosure provides a solution for this need.

### SUMMARY

In accordance with at least one aspect of this disclosure, a system for cooling a heat-generating component includes a cooling device having a first plate defining an inlet, an outlet, and an envelope for the heat-generating component. A second plate is mounted against the first plate and defines a converging-diverging (CD) nozzle therein, with an inlet end of the CD nozzle in fluid communication with the inlet of the first plate, and with an outlet end of the CD nozzle in fluid communication with the outlet of the first plate. The envelope for the heat-generating component is positioned between the inlet and the outlet to ensure thermal contact with a supersonic/transonic, two-phase fluid flow emerging from a throat of the CD nozzle.

A cover plate is mounted to the second plate opposite from the first plate, configured to securely enclose a fluid path from the inlet of the first plate, to the inlet end of the CD nozzle of the second plate, through the throat of the CD nozzle of the second plate, to the outlet end of the CD nozzle of the second plate, to the outlet of the first plate. In certain embodiments, the sealing plate is mounted to prevent any fluid leakage, ensuring proper sealing and structural integrity of the cooling device.

In certain embodiments, the first plate, the second plate, and the cover plate can be seamlessly integrated into a single assembly. In certain embodiments, the cooling device can be monolithic. In certain embodiments, the first plate, the second plate, and the cover plate can be separate components bonded together. In certain embodiments, certain components including at least the CD nozzle can be fabricated using additive manufacturing techniques, for example to enable complex internal geometries that enhance phase change and cooling efficiency.

In certain embodiments, a nozzle geometry of the CD nozzle can be dynamically adjustable to control (e.g., optimize) flow conditions based on real-time heat flux and cooling demands. In certain such embodiments, the CD nozzle can include a shape-memory alloy (SMA) element configured to deform in response to temperature changes. For example, in certain embodiments, at certain temperature thresholds (e.g., relatively elevated temperatures), the SMA element can actuate the throat by expanding or contracting to control flow rate and phase transition behavior dynamically.

In certain embodiments, the CD nozzle can be one of a plurality of CD nozzles arranged in parallel, each with a corresponding inlet and outlet. In certain embodiments, the system can further include a manifold connected in fluid communication with each corresponding inlet and outlet to distribute a working fluid evenly across the plurality of CD nozzles, ensuring uniform cooling over the heat-generating surface.

In certain embodiments, the CD nozzle can be one of a plurality of CD nozzles arranged in series to achieve a staged pressure drop and enhanced two-phase cooling performance.

In certain embodiments, the system can include a pressure controller operatively connected to both the inlet and outlet to control pressures actively for real-time cooling performance based on heat load variations. Such active or dynamic control can allow for optimized phase change and flow velocity, ensuring efficient two-phase flow and maximum heat removal.

In certain embodiments, the outlet of the CD nozzle can be positioned to generate a high velocity two-phase jet impingement cooling on the heat-generating component.

In accordance with at least one aspect of this disclosure, method of cooling a heat generating component can include supplying a pressurized liquid to an inlet of a converging-diverging (CD) nozzle, converting the pressurized liquid to two-phase flow with transonic/supersonic velocities at the throat, and transferring heat from the heat-generating component into the two-phase fluid. The CD nozzle can be or include any one or more embodiments (portions thereof) as described herein.

In certain embodiments, the nozzle geometry of the CD nozzle can be dynamically adjustable and in such embodiments, converting the pressurized liquid to two-phase flow can include controlling flow conditions based on real-time heat flux and cooling demands (e.g., by way of SMA element of the CD nozzle).

In certain embodiments, the method can further include actively controlling a pressure at both the inlet and outlet for real-time cooling performance based on heat load variations. In certain embodiments, transferring heat from the heat-generating component into the two-phase fluid includes generating a two-phase jet impingement cooling on the heat-generating component at the outlet side of the nozzle.

In certain embodiments, such as where a plurality of inlets and outlets are included, supplying the pressurized liquid can include supplying the pressurized liquid to the inlet via the manifold. In certain embodiments, such as where a plurality of CD nozzles are arranged in series, the method can include controlling a staged pressure drop to enhance two-phase cooling performance.

These and other features of the systems and methods of the subject disclosure will become more readily apparent to those skilled in the art from the following detailed description taken in conjunction with the drawings.

### BRIEF DESCRIPTION OF THE DRAWINGS

So that those skilled in the art to which the subject disclosure appertains will readily understand how to make and use the devices and methods of the subject disclosure without undue experimentation, embodiments thereof will be described in detail herein below with reference to certain figures, wherein:

FIG. 1 is a schematic perspective view of an embodiment of a system constructed in accordance with the present disclosure, showing the converging-diverging nozzle and the transonic/supersonic two-phase flow downstream of the throat cooling a heat generating electronic component;

FIG. 2 is a plan view of the system of FIG. 1, showing the heat generating electronic component; and

FIG. 3 is a cross-sectional side-elevation view of the system of FIG. 1, schematically showing the inlet and outlet for fluid, as well as the flow of heat from the heat generating electronic component;

FIG. 4 is a plan view of another embodiment of a system, showing multiple parallel converging-diverging nozzles in a cold plate arrangement;

FIG. 5 is a plan view of another embodiment of a system, showing multiple converging-diverging nozzles arranged in series with one another;

FIG. 6 is a plan view of an embodiment of the system of FIG. 1, showing a variant where the two-phase flow impinges on the heat generating electronic component; and

FIG. 7 is a cross-sectional side-elevation view of the system of FIG. 5, showing the impingement flow from the side.

### DETAILED DESCRIPTION

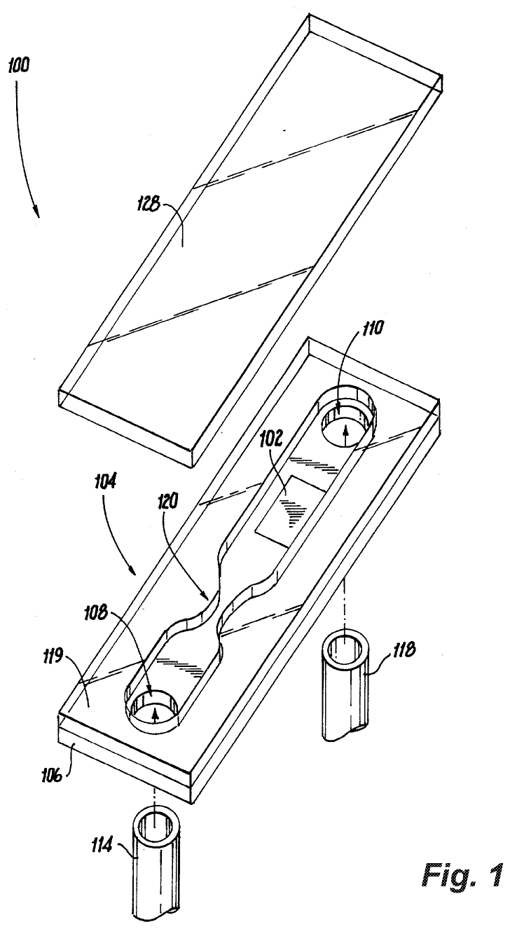

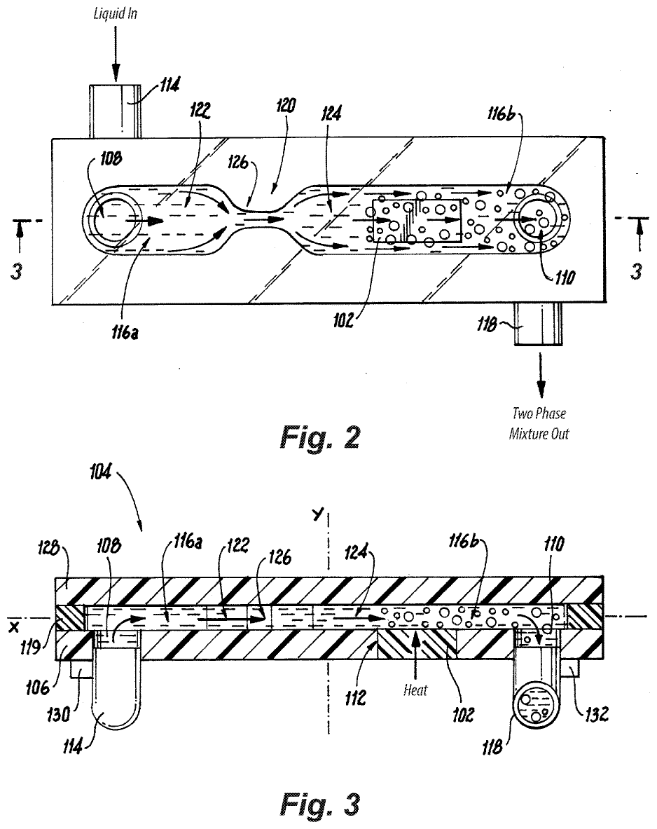

Reference will now be made to the drawings wherein like reference numerals identify similar structural features or aspects of the subject disclosure. For purposes of explanation and illustration, and not limitation, a partial view of an embodiment of a system in accordance with the disclosure is shown in FIG. 1. Other embodiments of systems in accordance with the disclosure, or aspects thereof, are provided in FIGS. 2-7, as will be described. The systems and methods described herein can be used to provide cooling, such as for heat generating electronic components.

This disclosure relates to using transonic and supersonic flows for cooling applications. Subsonic liquid flow enters a nozzle where it transitions to transonic and/or supersonic flow and a phase change occurs downstream the inlet, resulting in two-phase flow at the outlet. The nozzle is in certain embodiments, a converging-diverging conduit. In certain embodiments other suitable nozzle geometries could be utilized, for example, a straight channel upstream and a diverging channel downstream. Depending on the pressure difference between the inlet and outlet, the flow exhibits transonic and supersonic velocities once it reaches the sonic velocity. These downstream flow conditions can provide a favorable cooling capability to remove high heat fluxes for various industrial applications.

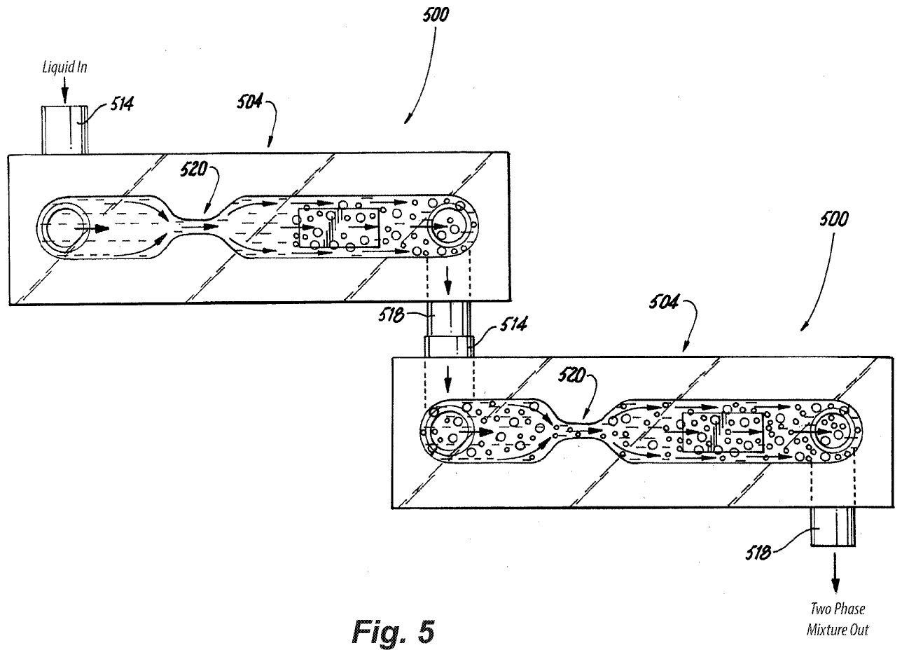

In accordance with at least one aspect of this disclosure, in FIG. 1, a system 100 for cooling a heat-generating component 102 is shown. The system 100 includes a cooling device 104 having a first plate 106 defining an inlet 108, an outlet 110, and an envelope 112 for the heat-generating component 102. An inlet conduit 114 is fluidically connected to the first plate 106 to supply a single-phase working fluid 116a to the inlet 108 of the first plate 106 and an outlet conduit 118 is fluidically connected to the outlet 110 of the first plate 106 to carry a two-phase working fluid 116b away from the first plate 106 to a downstream component. In certain embodiments, the downstream component can be another cooling device for example as described further with respect to FIG. 5. The working fluid 116a is supplied to the inlet 108 of the first plate 106 in a single phase (e.g., as a liquid) and the working fluid 116b exits the first plate 106 through the outlet conduit in a two-phase state (i.e., liquid and gas mixture).

A second plate 119 is mounted against the first plate 106 and defines a nozzle 120 (e.g., a converging-diverging (CD) nozzle) therein having an inlet 122 and outlet 124, and a throat 126 therebetween. The throat 126 of the CD nozzle 120 is configured to accelerate the working fluid 116a entering the nozzle 120 from subsonic flow to transonic or supersonic flow the outlet 124 of the CD nozzle 120 towards the heat generating component 102 and the outlet 110 of the first plate 106. The inlet end 122 of the CD nozzle 120 is in fluid communication with the inlet 108 of the first plate 106, and the outlet end 124 of the CD nozzle 120 is in fluid communication with the outlet 110 of the first plate 106 creating a flow path for the working fluid 116 flow through the cooling device 104, e.g., from the inlet conduit 114, through the inlet 108 of the first plate 106, through the inlet 122 of the CD nozzle 120, into and out of the throat 126, through the outlet 124 of the CD nozzle 120, through the outlet of the first plate 110 and to the outlet conduit 118.

The working fluid 116a enters the nozzle subsonic and undergoes a phase change process along the nozzle 120 (e.g., at the throat 126), resulting in a two-phase mixture of liquid and vapor at the outlet 124 of the nozzle 120. At a sufficiently high pressure drop, the flow 116a passes the sonic conditions, e.g., around the throat 126 in the converging-diverging nozzle 120, and continues as a supersonic two-phase flow 116b. In a conventional CD nozzle, downstream of the throat, the geometry of the nozzle 120 diverges and the flow is expanded to supersonic flow, causing the static pressure and temperature to decrease from the throat to the exit of the nozzle because of the Joule-Thomson and compressibility effects.

In the present case, since a phase change working fluid is utilized rather than a single-phase fluid, the effective sonic velocity in the two-phase mixture exiting the inventive CD nozzle 120 can be an order of magnitude lower than in a single-phase liquid, therefore enabling supersonic conditions at moderate flow velocities unlike conventional CD nozzles. Thus, the combination of low fluid temperatures and high velocities of the downstream flow ensures effective high heat removal from the heated surface of the heat generating component 102. In certain embodiments, the working fluid can be carbon dioxide (CO₂). CO₂ has uniquely high Joule-Thomson coefficients (2-12 K/MPa), low viscosity enabling high-velocity flow, and favorable thermodynamic properties near the critical point making it a particularly effective working fluid in this application.

As best seen in FIG. 3, a cover 128 plate can be mounted to the second plate 119 opposite the first plate 106, configured to enclose the working fluid flow path within the cooling device 104. In this configuration, the working fluid flow path is defined between the first plate 106 and the cover plate 128 in the Y direction, and defined through the second plate 119 in the X direction. In certain embodiments, one or more sealing components can be included between the cover plate 128 and the second plate 119 to prevent any fluid leakage from the cooling device thereby ensuring proper sealing and structural integrity of the cooling device.

Still with reference to FIGS. 1-3, the envelope 112 retaining or seating the heat-generating component 102 is positioned between the inlet 108 and the outlet 110 of the first plate 106, and is also between the outlet 124 of the CD nozzle 120 and the outlet 110 of the first plate 106 to ensure thermal contact between the heat generating component 102 and the supersonic/transonic working fluid flow 116b emerging from the throat 126 of the CD nozzle 120 (e.g., at the outlet side of the CD nozzle). The envelope 112, in certain embodiments, is configured such that the two-phase working fluid 116b is in thermal communication with the heat generating component, 102 but the two-phase working fluid 116b does not directly contact the heat generating component 102. In such embodiments, the cooling of the first plate 106 thereby cools the heat generating component 102.

In certain embodiments, the system can include a pressure controller, e.g., modules 130, 132, operatively connected to both the inlet 108 and outlet 110 of the first plate 106 to control pressures actively for real-time cooling performance based on heat load variations. Such active or dynamic control can allow for optimized phase change and flow velocity, ensuring efficient two-phase flow and maximum heat removal.

In certain embodiments, the first plate 106, the second plate 119, and the cover plate 128 can be separate components bonded together, such as shown in FIGS. 1-3 for example. In certain embodiments, the first plate 106, the second plate 119, and the cover plate 128 can be seamlessly integrated into a single assembly, and in certain embodiments, the cooling device 104 can be monolithic. In certain embodiments, certain components, including at least the CD nozzle 120, can be fabricated using additive manufacturing techniques, for example to enable complex internal geometries that enhance phase change and cooling efficiency. In certain embodiments, an entirety of the cooling device 104 can be additively manufactured.

In certain embodiments, a nozzle geometry of the CD nozzle 120 can be dynamically adjustable to control (e.g., optimize) flow conditions based on real-time heat flux and cooling demands. For example, in certain such embodiments, the CD nozzle 120 can include a shape-memory alloy (SMA) element configured to deform in response to temperature changes or at certain temperature thresholds (e.g., relatively elevated temperatures). At such temperatures, the SMA element can actuate the throat 126 by expanding or contracting to control flow rate and phase transition behavior dynamically.

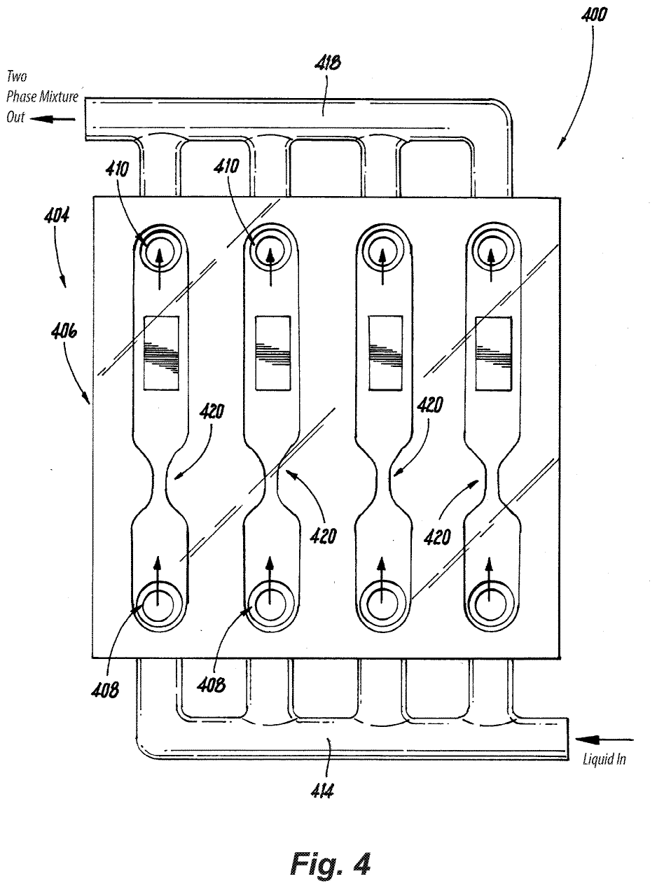

In certain embodiments, such as shown in FIGS. 4 and 5, other embodiments of a system is shown, which is similar to the system and cooling device described with respect to FIGS. 1-3. For brevity, like components described above with respect to FIGS. 1-3 will not be described again while referencing FIGS. 4 and 5. The system 400 and cooling device 404 of FIG. 4 can include a plurality of CD nozzles 420 arranged in parallel, each with a corresponding inlet 408 and outlet 410 defined in the first plate 406. In such a configuration, the inlet conduit can be an inlet manifold 414, and the outlet conduit can be an outlet manifold 418, as shown. The inlet manifold 414 can be configured to distribute the working fluid evenly across the plurality of CD nozzles 420, ensuring uniform cooling over the heat-generating surface. As shown in FIG. 5, the system 500 can include a plurality of cooling devices 504, each having a single CD nozzle 520 defined in each respective plate 506. Here, the nozzles 120 are arranged in series, or daisy chained, to allow for a controlled pressure drop and enhanced two-phase cooling performance.

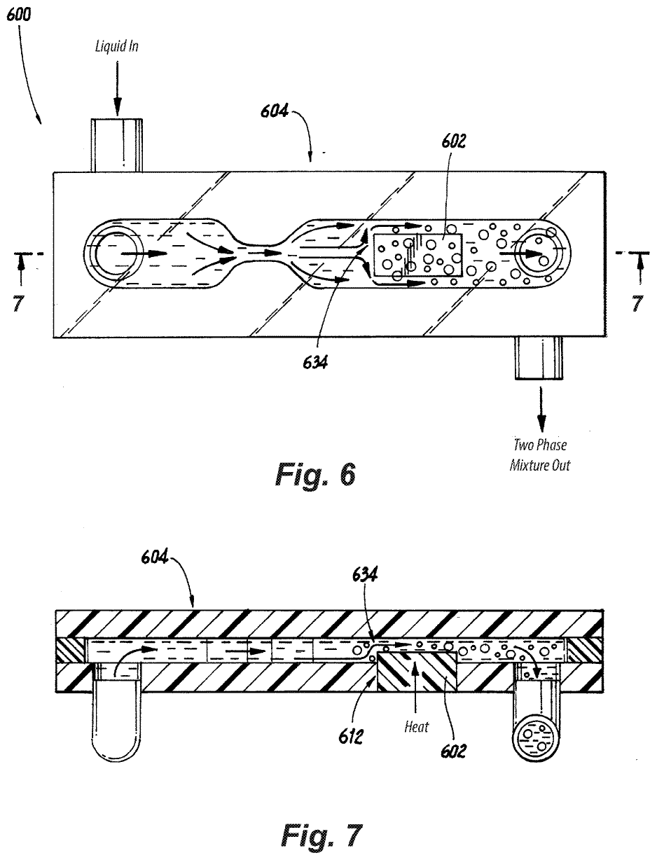

In certain embodiments, such as shown in FIGS. 6 and 7, another embodiment of a system 600 and cooling device 604 is shown, which is similar to the system and cooling device described with respect to FIGS. 1-3. For brevity, like components described above with respect to FIGS. 1-3 will not be described again while referencing FIGS. 6 and 7. Here, the envelope 612 can extend into the working fluid flow path and into the outlet side of the CD nozzle, or can allow the heat-generating component 102 to extend into the working fluid flow path. The transonic/supersonic flow exiting the throat of the CD nozzle thus generates a high velocity two-phase impingement jet 634, where the two-phase working fluid 116b exits the CD nozzle at high velocity, impinges on the heat generating component 602, absorbing heat through continued evaporation and cooling the heat-generating component 602. In this example, the two-phase working fluid does directly contact the heat-generating component 102.

In accordance with at least one aspect of this disclosure, method of cooling a heat generating component (e.g., component 102) is described with reference to FIG. 2. The method can include supplying a pressurized liquid (e.g., working fluid 116a) to an inlet of a converging-diverging (CD) nozzle (e.g., nozzle 120 via inlet conduit 114), converting the pressurized liquid to two-phase flow (e.g., working fluid 116b)with transonic/supersonic velocities at the throat of the CD nozzle (e.g., throat 126), and transferring heat from the heat-generating component into the two-phase working fluid. The method can employ any one or more embodiments of the cooling device 104, 404, 504, 604, portions thereof as described herein.

Embodiments of this disclosure provide novel insights into the thermal behavior of two-phase supersonic flow, particularly where phase changes play a significant role in temperature drops. The substantial temperature drops demonstrate a promising cooling approach, utilizing transonic and supersonic two-phase flow to remove high heat fluxes from the heated surfaces of the heat generating components, which can include for example, electronics lasers, GPU, CPU, power amplifier, which often experience intense hot spots. The heat can be transferred from a cooled plate (e.g., as shown in FIGS. 1-5) or by directly liquid cooling of electronic chips (e.g., as shown in FIGS. 6 and 7). Certain embodiments of the system can also be applied to cool high power electronics, such as graphics processing units (GPUs), central processing units (CPUs), laser diodes, and power amplifiers.

Systems and methods as disclosed herein provide benefits/advantages over traditional techniques, including a significant enhancement of cooling with environmentally friendly fluids, improved thermal management and heat transfer capabilities. Certain embodiments of the system and method described herein can be used in applications including high-power electronic cooling, advanced thermal management, phase-change cooling, microchannel heat exchangers, data center cooling, semiconductor cooling, energy-efficient thermal solutions, aerospace thermal systems, and sustainable cooling technologies, electronics manufacturing, power electronics, renewable energy systems, automotive thermal management, and green technology solutions.

Accordingly, the methods and systems of the present disclosure, as described above and shown in the drawings, provide for cooling such as for heat generating electronic components like processors and other chips. While the apparatus and methods of the subject disclosure have been shown and described with reference to certain embodiments, those skilled in the art will readily appreciate that changes and/or modifications may be made thereto without departing from the scope of the subject disclosure.

What is claimed is:

1. A system for cooling a heat-generating component comprising:
first plate defining an inlet, an outlet, and an envelope for the heat-generating component;
a second plate mounted against the first plate and defining a converging-diverging (CD) nozzle therein, with an inlet end of the CD nozzle in fluid communication with the inlet of the first plate, with an outlet end of the CD nozzle in fluid communication with the outlet of the first plate, and wherein the envelope for the heat-generating component is positioned between the inlet and the outlet to ensure thermal contact with a supersonic/transonic, two-phase fluid flow emerging from a throat of the CD nozzle; and
a cover plate mounted to the second plate opposite from the first plate, configured to securely enclose a fluid path from the inlet of the first plate, to the inlet end of the CD nozzle of the second plate, through the throat of the CD nozzle of the second plate, to the outlet end of the CD nozzle of the second plate, to the outlet of the first plate.

2. The system as recited in claim 1, wherein the first plate, the second plate, and the cover plate are seamlessly integrated into a single assembly.

3. The system as recited in claim 1, wherein the first plate, the second plate, and the cover plate are separate components bonded together.

4. The system as recited in claim 1, wherein at least the CD nozzle is fabricated using additive manufacturing techniques.

5. The system as recited in claim 1, wherein a nozzle geometry of the CD nozzle is dynamically adjustable to control flow conditions based on real-time heat flux and cooling demands.

6. The system as recited in claim 5, wherein the CD nozzle includes a shape-memory alloy (SMA) element configured to deform in response to temperature changes such that the SMA element actuates the throat, expanding or contracting to control flow rate and phase transition behavior dynamically.

7. The system as recited in claim 1, wherein the CD nozzle is one of a plurality of CD nozzles arranged in parallel, each with a corresponding inlet and outlet.

8. The system as recited in claim 7, further comprising a manifold connected in fluid communication with each corresponding inlet and outlet to distribute a working fluid evenly across the plurality of CD nozzles, ensuring uniform cooling over the heat-generating surface.

9. The system as recited in claim 1, wherein the CD nozzle is one of a plurality of CD nozzles in series to achieve a staged pressure drop and enhanced two-phase cooling performance.

10. The system as recited in claim 1, further comprising a pressure controller operatively connected to both the inlet and outlet to control pressures actively for real-time cooling performance based on heat load variations.

11. The system as recited in claim 1, wherein the outlet of the CD nozzle is positioned to generate two-phase jet impingement cooling on the heat-generating component.

12. A method of cooling a heat generating component comprising:
supplying a pressurized liquid to an inlet of a converging-diverging (CD) nozzle;
converting the pressurized liquid to two-phase flow with transonic/supersonic velocities at the throat; and
transferring heat from the heat-generating component into the two-phase fluid.

13. The method as recited in claim 12, wherein at least the CD nozzle is fabricated using additive manufacturing techniques.

14. The method as recited in claim 12, wherein a nozzle geometry of the CD nozzle is dynamically adjustable, wherein converting the pressurized liquid to two-phase flow includes controlling flow conditions based on real-time heat flux and cooling demands.

15. The method as recited in claim 14, wherein the CD nozzle includes a shape-memory alloy (SMA) element configured to deform in response to temperature changes wherein at relatively elevated temperatures, the SMA element actuates the throat, expanding or contracting to control flow rate and phase transition behavior dynamically.

16. The method as recited in claim 12, wherein the CD nozzle is one of a plurality of CD nozzles arranged in parallel, each with a corresponding inlet and outlet.

17. The method as recited in claim 16, further comprising a manifold connected in fluid communication with each corresponding inlet and outlet to distribute a working fluid evenly across the plurality of CD nozzles, ensuring uniform cooling over the heat-generating surface.

18. The method as recited in claim 12, wherein the CD nozzle is one of a plurality of CD nozzles in series to achieve a staged pressure drop and enhanced two-phase cooling performance.

19. The method as recited in claim 12, further comprising a pressure controller actively controlling pressure at both the inlet and outlet for real-time cooling performance based on heat load variations.

20. The method as recited in claim 12, wherein transferring heat from the heat-generating component into the two-phase fluid includes the outlet of the CD nozzle being positioned to generate two-phase jet impingement cooling on the heat-generating component.
